(19) United States
(12) Patent Application Publication
(10) Pub. No.: US 2026/0040923 A1
(43) Pub. Date: Feb. 5, 2026

(54) THREE-DIMENSIONAL STACK WITH BACKSIDE POWER DISTRIBUTION NETWORK (BSPDN) CONTACTS

(71) Applicant: QUALCOMM Incorporated, San Diego, CA (US)

(72) Inventors: Jihong CHOI, San Diego, CA (US); Giridhar NALLAPATI, San Diego, CA (US); Periannan CHIDAMBARAM, San Diego, CA (US)

(21) Appl. No.: 19/288,679

(22) Filed: Aug. 1, 2025

Related U.S. Application Data
(60) Provisional application No. 63/678,597, filed on Aug. 2, 2024.

(51) Int. Cl. H01L 23/00; H01L 23/522; H01L 23/528; H01L 25/065

(52) U.S. Cl. CPC H01L 24/08; H01L 23/5226; H01L 23/5283; H01L 24/80; H01L 25/0657; H01L 2224/08145; H01L 2224/80895; H01L 2224/80896; H01L 2225/06541; H01L 2225/06565

(57) ABSTRACT

Disclosed is an integrated circuit device. In some aspects, a device includes a first wafer including a first dielectric layer, a first set of bonding pads disposed in the first dielectric layer and a first circuit disposed on the first dielectric layer, and a second wafer including a second dielectric layer, a second set of bonding pads disposed in the second dielectric layer and a second circuit disposed on the second dielectric layer. The device further includes through-vias including at least one power via in the second wafer, and a backside power distribution network (BSPDN) layer disposed on the second wafer. The first set of bonding pads is bonded with the second set of bonding pads.

### CROSS-REFERENCE TO RELATED APPLICATIONS

The present application for patent claims the benefit of U.S. Provisional Application No. 63/678,597, entitled “THREE-DIMENSIONAL STACK WITH BACKSIDE POWER DISTRIBUTION NETWORK (BSPDN) CONTACTS,” filed Aug. 2, 2024, assigned to the assignee hereof, and expressly incorporated herein by reference in its entirety.

### BACKGROUND OF THE DISCLOSURE

### 1. Field of the Disclosure

This disclosure relates generally to integrated circuit devices, and more specifically, to integrated circuit devices having a three-dimensional stack with backside power distribution network (BSPDN) contacts, and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device.

In mobile devices, such as phones or smart watches, the sizes of IC devices may be severely constrained. For example, both the surface area and the height of an IC in a mobile device may be severely limited by the overall size of the mobile device. Meanwhile, IC devices may be increasingly required to possess ever greater computational capacity and perform an ever greater number of functions, for example, various functions according to various communication protocols (e.g., 4G, 5G, 5G+, 6G, Wi-Fi, Bluetooth, and/or other protocols), in mobile devices. Consequently, there may be stronger demands for placing an ever greater number of circuit components within the physical size constraints of an IC device. However, the number of components that can be placed within a given area of an IC device may be limited by the process node, and more advanced process nodes (e.g., smaller feature sizes) may typically entail higher manufacturing costs.

Accordingly, there is a need for improved structures for IC devices and methods of manufacturing the same to address the above-noted issues.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In some aspects, a device includes a first wafer including a first dielectric layer; a first plurality of bonding pads disposed in the first dielectric layer; and a first circuit disposed on the first dielectric layer; and a second wafer including a second dielectric layer; a second plurality of bonding pads disposed in the second dielectric layer; and a second circuit disposed on the second dielectric layer; a plurality of through-vias including at least one power via through at least the second dielectric layer in the second wafer; and a backside power distribution network (BSPDN) layer disposed on the second wafer, the BSPDN layer including at least one component electrically connected to the at least one power via, wherein the first plurality of bonding pads is bonded with the second plurality of bonding pads.

In some aspects, a method of manufacturing a device includes forming a first wafer comprising a first dielectric layer, a first plurality of bonding pads disposed in the first dielectric layer, and a first circuit disposed on the first dielectric layer; forming a second wafer comprising a second dielectric layer, a second plurality of bonding pads disposed in the second dielectric layer, and a second circuit disposed on the second dielectric layer; forming a plurality of through-vias including at least one power via in the second wafer; forming a backside power distribution network (BSPDN) layer disposed on the second wafer; and bonding the first plurality of bonding pads with the second plurality of bonding pads.

In some aspects, an apparatus includes a device that comprises: a first wafer including a first dielectric layer; a first plurality of bonding pads disposed in the first dielectric layer; and a first circuit disposed on the first dielectric layer; and a second wafer including a second dielectric layer; a second plurality of bonding pads disposed in the second dielectric layer; and a second circuit disposed on the second dielectric layer; a plurality of through-vias including at least one power via in the second wafer; and a backside power distribution network (BSPDN) layer disposed on the second wafer, wherein the first plurality of bonding pads is bonded with the second plurality of bonding pads.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIGS. 1A and 1B illustrate cross-sectional views of first and second wafers before they are bonded, according to aspects of the disclosure.

FIGS. 2A-2C illustrate structures at various stages of manufacturing an IC device, according to aspects of the disclosure.

FIG. 3 illustrates a cross-sectional view of an IC device, according to aspects of the disclosure.

FIG. 4 illustrates a perspective view of an IC device, according to aspects of the disclosure.

FIG. 5 illustrates a method for manufacturing a device, according to aspects of the disclosure.

FIG. 6 illustrates a mobile device that may incorporate one or more IC devices and/or IC packages described herein, according to aspects of the disclosure.

FIG. 7 illustrates various electronic devices that may incorporate one or more IC devices and/or IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

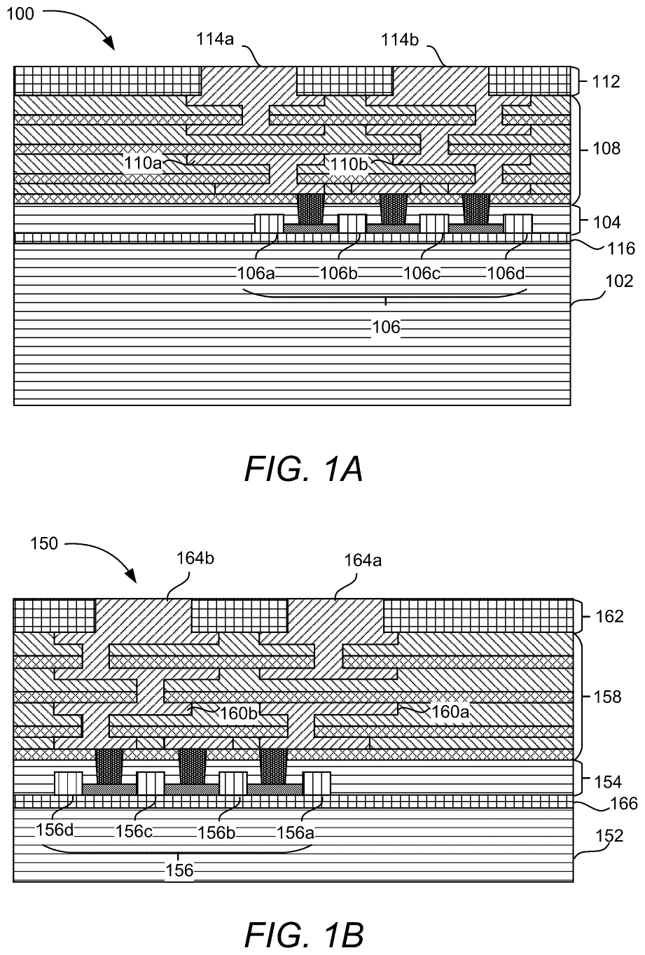

FIGS. 1A and 1B illustrate cross-sectional views of first and second wafers before they are bonded, according to aspects of the disclosure. FIG. 1A illustrates an example of the cross-sectional view of a first wafer 100 which includes a bulk silicon layer 102 and a dielectric layer 104 for a first circuit 106 disposed on the bulk silicon layer 102. In some aspects, the first circuit 106 may include active electronic components 106a, 106b, 106c and 106d such as transistors, for example, silicon field effect transistors (FETs). The first circuit 106 may also include other types of circuit components within the scope of the disclosure.

In some aspects, the first wafer 100 may also include one or more dielectric layers and metal contacts disposed within the dielectric layers. In the example illustrated in FIG. 1A, a plurality of dielectric layers 108 and a plurality of metal contacts (e.g., metal contacts 110a and 110b) disposed within the dielectric layers 108 are shown. In some aspects, the dielectric layers 108 may be a low dielectric constant (low-k) material, an oxide material, or the like. In some aspects, the metal contacts 110a and 110b may be copper or another metal, for example, to provide metal wiring for the components of the first circuit 106.

In some aspects, the first wafer 100 may include a dielectric layer (e.g., an oxide layer 112) disposed on the dielectric layers 108, and a plurality of bonding pads (e.g., bonding pads 114a and 114b) disposed within the oxide layer 112. In some aspects, the oxide layer 112 may comprise a material such as silicon carbon nitride (SiCN), or the like. In some aspects, the bonding pads 114a and 114b may be hybrid bonding pads such as hybrid copper bonding (HCB) pads. In some aspects, a stop layer 116 may be provided between the components of the first circuit 106 and the bulk silicon layer 102. The stop layer 116 may be silicon germanium (SiGe), silicon oxide (SiOₓ), silicon nitride (SIN), polysilicon, or the like. In some implementations, a thin silicon layer may be provided between the dielectric layer 104 and the stop layer 116.

FIG. 1B illustrates an example of the cross-sectional view of a second wafer 150 which includes a bulk silicon layer 152 and a dielectric layer 154 for a second circuit 156 disposed on the bulk silicon layer 152. In some aspects, the second circuit 156 may include active electronic components 156a, 156b, 156c and 156d such as transistors, for example, silicon field effect transistors (FETs). The second circuit 156 may also include other types of circuit components within the scope of the disclosure.

In some aspects, the second wafer 150 may also include one or more dielectric layers and metal contacts disposed within the dielectric layers. In the example illustrated in FIG. 1B, a plurality of dielectric layers 158 and a plurality of metal contacts (e.g., metal contacts 160a and 160b) disposed within the dielectric layers 158 are shown. In some aspects, the dielectric layers 158 may be a low-k material, an oxide material, or the like. In some aspects, the metal contacts 160a and 160b may be copper or another metal, for example, to provide metal wiring for the components of the second circuit 156.

In some aspects, the second wafer 150 may include a dielectric layer (e.g., an oxide layer 162) disposed on the dielectric layers 158, and a plurality of bonding pads (e.g., bonding pads 164a and 164b) disposed within the oxide layer 162. In some aspects, the oxide layer 162 may comprise a material such as SiCN, or the like. In some aspects, the bonding pads 164a and 164b may be hybrid bonding pads such as HCB pads. In some implementations, a stop layer 166 may be provided between the dielectric layer 154 and the bulk silicon layer 152. The stop layer 166 may be SiGe, SiOₓ, SiN, polysilicon, or the like. In some implementations, the second wafer 150 may be a very large scale integration (VSLI) silicon wafer without a stop layer.

In the examples shown in FIGS. 1A and 1B, the first and second wafers 100 and 150 may have similar structures except that the circuits and metal contacts within various layers of the first and second wafers 100 and 150 may be offset from each other. In some aspects, after the first wafer 100 in FIG. 1A is flipped upside down, the bonding pads 114a and 114b of the first wafer 100 may be positioned to match the bonding pads 164a and 164b of the second wafer 150, respectively.

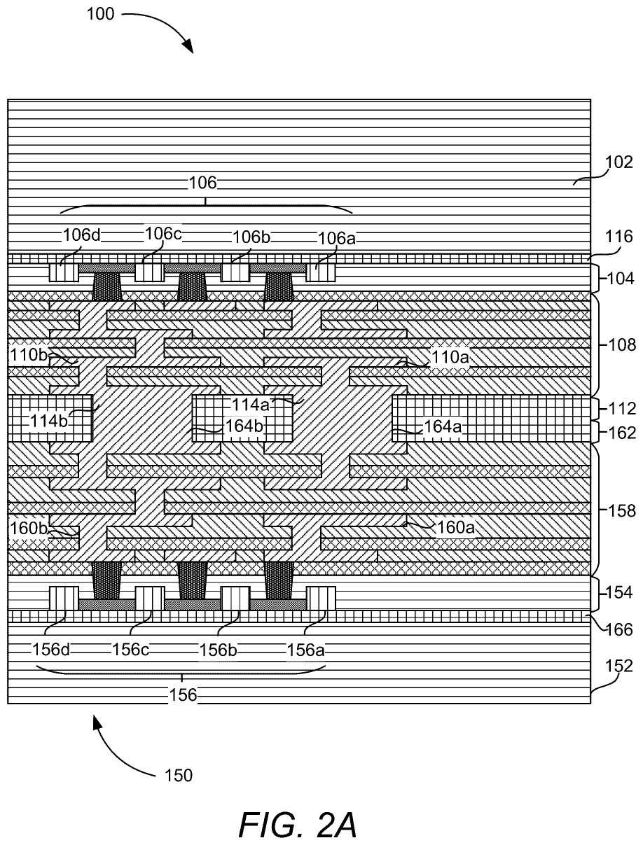

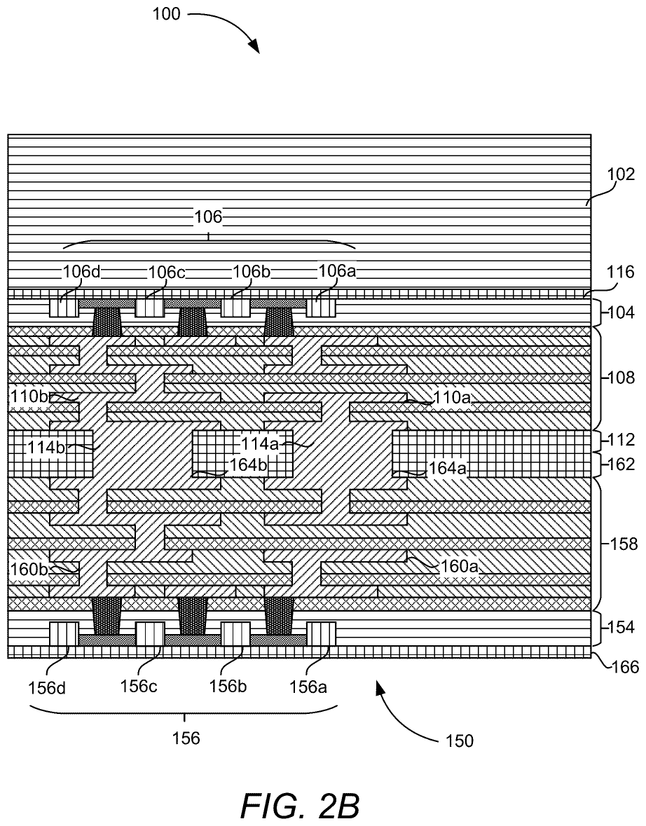

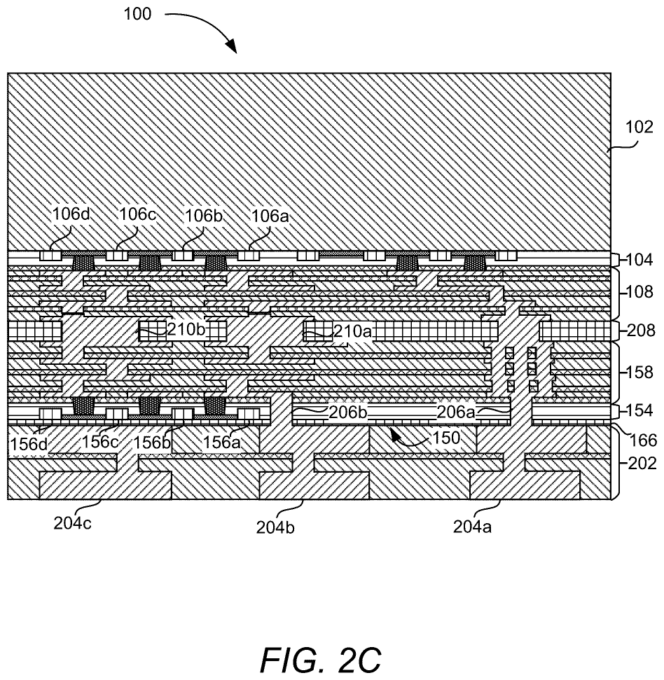

FIGS. 2A-2C illustrate structures at various stages of manufacturing an IC device, according to aspects of the disclosure. FIG. 2A illustrates a bonded structure after the first wafer 100 of FIG. 1A is flipped upside down and bonded with the second wafer 150 of FIG. 1B. In some aspects, the bonding of the first wafer 100 to the second wafer 150 may be achieved by a wafer-on-wafer (WOW) process. In some aspects, the bonding of the first wafer 100 to the second wafer 150 may be achieved by a hybrid bonding process, for example, an HCB process, to provide electrical connections between the corresponding bonding pads of the first and second wafers 100 and 150 (e.g., bonding of bonding pads 114a and 114b to bonding pads 164a and 164b, respectively). In some aspects, a tight pitch (e.g., a pitch of 1.4 μm or less) for the bonding pads may be achieved through a WOW hybrid bonding process.

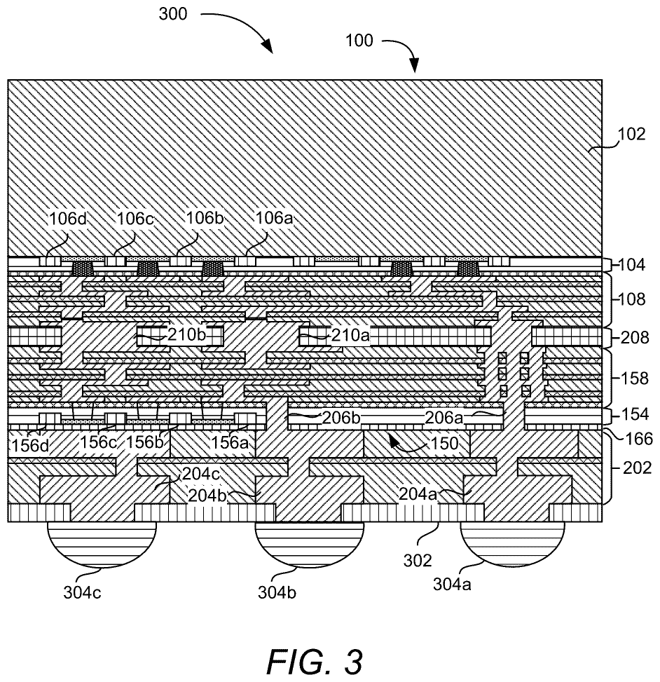

FIG. 2B illustrates the bonded structure of FIG. 2A after bulk silicon on one of the wafers is thinned by a thinning process. For example, the bulk silicon layer 152 on the second wafer 150 may be removed by a thinning process, such that further processes (e.g., silicon fabrication back end of line (BEOL) or backside power distribution network (BSPDN) processes illustrated in FIG. 2C and FIG. 3) may be applied to provide electrical connections to the components of the second circuit 156 (e.g., electronic components 156a, 156b, 156c and 156d) as well as the components of the first circuit 106 (e.g., electronic components 106a, 106b, 106c and 106d).

FIG. 2C illustrates a structure after a BSPDN process (e.g., through-via for BSPDN to front side connection) are applied to the structure of FIG. 2B to form a BSPDN structure 202. In the example illustrated in FIG. 2C, the BSPDN structure 202 is formed on the stop layer 166. In some aspects, the BSPDN structure 202 comprises a dielectric material, and a plurality of metal contacts (e.g., metal contacts 204a, 204b and 204c) are formed within the dielectric material. In some aspects, the metal contacts 204a, 204b and 204c may be copper or another metal. In some aspects, the BSPDN structure 202 may be formed by applying the BSPDN process to the backside of the second wafer 150, for example.

In some aspects, one or more vias (e.g., vias 206a and 206b) may be formed through the stop layer 166 and the dielectric layer 154 to provide electrical connections with circuit components within the first and second wafers 100 and 150. In some aspects, the vias may be nano through-silicon vias (nano TSVs) for electrical connections through a silicon wafer or die. In some aspects, at least one of the vias (e.g., via 206a) may serve as a power via for the IC device. In the example illustrated in FIG. 2C, the vias 206a and 206b are electrically connected to the metal contacts 204a and 204b within the BSPDN structure 202, respectively. Those of skill in the art will appreciate that the structures depicted in FIGS. 1A and 1B before bonding and the structures depicted in FIGS. 2A and 2B after bonding may be repeated over respective wafers. It will be appreciated that the BSPDN structure 202 may extend over the second wafer 150 with one or more additional vias (e.g., via 206a) and one or more additional metal contacts (e.g., metal contact 204a), and one or more of those vias may serve as a power via for the IC device.

For simplicity of illustration, in FIG. 2C, the oxide layer 112 of the first wafer 100 and the oxide layer 162 of the second wafer 150 are shown as a single oxide layer 208 after WOW hybrid bonding. Likewise, bonding pads 114a and 114b of the first wafer 100 and bonding pads 164a and 164b of the second wafer 150 are shown as bonded bonding pads 210a and 210b, respectively, after WOW hybrid bonding.

FIG. 3 illustrates a cross-sectional view of an IC device 300 after the first and second wafers are bonded and packaging processes are applied, according to aspects of the disclosure. After the BSPDN structure 202 and the metal contacts 204a, 204b and 204c are formed on the second wafer 150, one or more additional packaging processes may be applied to form the IC device 300. For example, as shown in FIG. 3, a passivation layer 302 may be formed on the BSPDN structure 202, and a plurality of bumps (e.g., bumps 304a, 304b and 304c) may be formed on the passivation layer 302. For example, the bumps 304a, 304b and 304c may be electrically connected to the metal contacts 204a, 204b and 204c of the BSPDN structure 202, respectively.

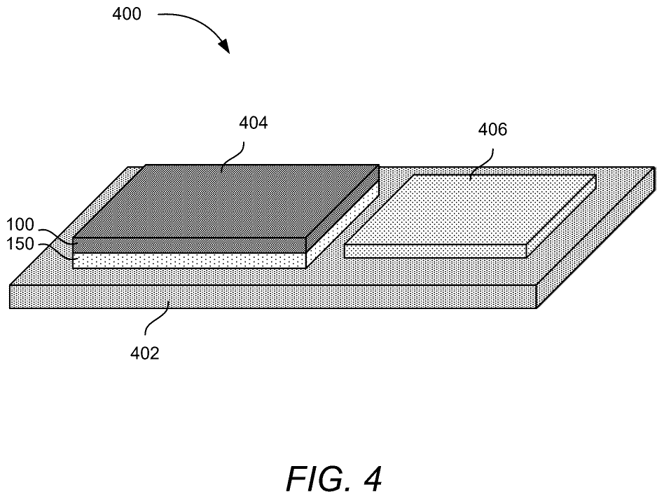

FIG. 4 illustrates a perspective view of an IC device after the first and second wafers are bonded and packaging processes are applied, according to aspects of the disclosure. In the example illustrated in FIG. 4, a multi-die chip device 400 may include a package substrate 402 (or various forms of interposers, e.g., a silicon interposer or a redistribution layer (RDL) interposer) and multiple dies (e.g., dies 404 and 406) disposed thereon. In the example shown in FIG. 4, the first die 404 is a multi-stack die while the second die 406 is a single-stack die. The first die 404 may include a first wafer 100 and a second wafer 150, as shown in FIG. 3, bonded together by a bonding process, such as a WOW hybrid bonding process, for example.

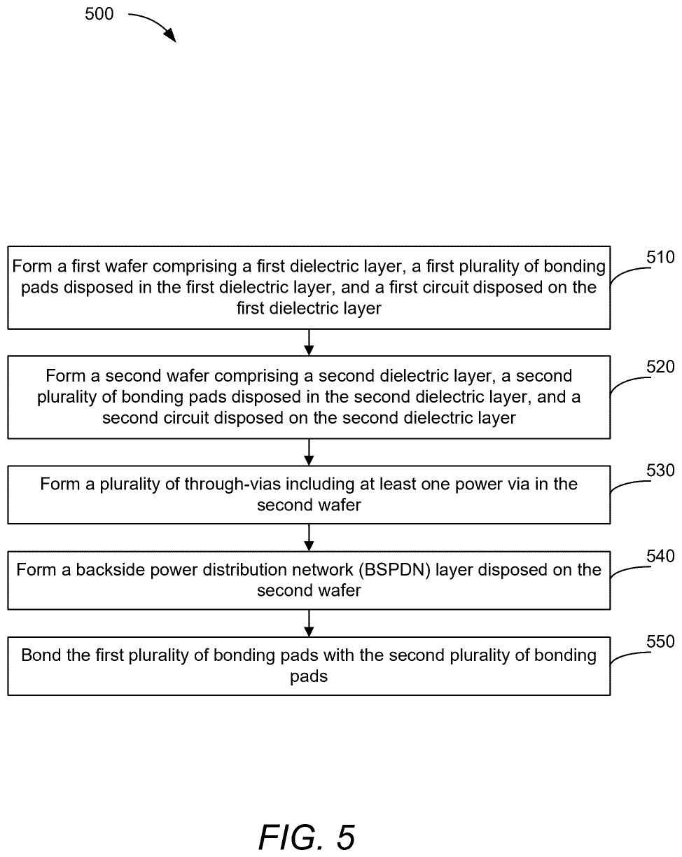

FIG. 5 illustrates a method 500 of manufacturing a device (for example, IC device 300 as shown in FIG. 3), according to aspects of the disclosure. In some aspects, the device may be a central processing unit (CPU) device, a graphic processing unit (GPU) device, a digital IC device, an analog IC device, a mixed-signal IC device, a radio frequency (RF) IC device, a system-on-chip (SOC) device, or a passive device such as a silicon capacitor, or the like.

At operation 510, a first wafer (e.g., wafer 100) may be formed. In some aspects, the first wafer (e.g., wafer 100) may include a first dielectric layer (e.g., oxide layer 112), a first plurality of bonding pads (e.g., bonding pads 114a and 114b) disposed in the first dielectric layer (e.g., oxide layer 112), and a first circuit (e.g., circuit 106) disposed on the first dielectric layer (e.g., oxide layer 112).

At operation 520, a second wafer (e.g., wafer 150) may be formed. In some aspects, the second wafer (e.g., wafer 150) may include a second dielectric layer (e.g., oxide layer 162), a second plurality of bonding pads (e.g., bonding pads 164a and 164b) disposed in the second dielectric layer (e.g., oxide layer 162), and a second circuit (e.g., circuit 156) disposed on the second dielectric layer (e.g., oxide layer 162).

At operation 530, a plurality of through-vias (e.g., vias 206a and 206b) including at least one power via (e.g., via 206a) may be formed in the second wafer (e.g., wafer 150). The at least one power via and/or one or more other through-vias of the plurality of through-vias may be formed through at least the second dielectric layer in the second wafer.

At operation 540, a backside power distribution network (BSPDN) layer (e.g., BSPDN structure 202) may be formed. In some aspects, the BSPDN layer (e.g., BSPDN structure 202) may be disposed on the second wafer (e.g., wafer 150). The BSPDN layer may include at least one component electrically connected to the at least one power via.

At operation 550, the first plurality of bonding pads (e.g., bonding pads 114a and 114b) may be bonded with the second plurality of bonding pads (e.g., bonding pads 164a and 164b). In some aspects, operation 550 may be performed after operation 520 and before operation 530. In some aspects, a thinning process may be performed after the first plurality of bonding pads are bonded to the second plurality of bonding pads at operation 550.

In some aspects, the method 500 may further include additional implementations, such as any single implementation or any combination of implementations described below and/or in connection with one or more other processes described elsewhere herein.

In some aspects, the first plurality of bonding pads (e.g., bonding pads 114a and 114b) may comprise a first plurality of hybrid bonding pads, and the second plurality of bonding pads (e.g., bonding pads 164a and 164b) may comprise a second plurality of hybrid bonding pads.

In some aspects, bonding the first plurality of bonding pads (e.g., bonding pads 114a and 114b) with the second plurality of bonding pads (e.g., bonding pads 164a and 164b) may comprise hybrid copper bonding the first plurality of bonding pads (e.g., bonding pads 114a and 114b) with the second plurality of bonding pads (e.g., bonding pads 164a and 164b).

In some aspects, bonding the first plurality of bonding pads (e.g., bonding pads 114a and 114b) with the second plurality of bonding pads (e.g., bonding pads 164a and 164b) may comprise wafer-on-wafer bonding the first plurality of bonding pads (e.g., bonding pads 114a and 114b) with the second plurality of bonding pads (e.g., bonding pads 164a and 164b).

Although FIG. 5 shows example operations of a method 500, in some implementations, the method 500 may include additional operations, fewer operations, different operations, or differently arranged operations from those depicted in FIG. 5. Additionally, or alternatively, two or more of the operations of the method 500 may be performed in parallel, or may be performed in a temporal sequence different from the order listed or described.

A technical advantage of various aspects of the disclosure is that, by bonding two wafers with circuit components and interconnects using a wafer-on-wafer (WOW) hybrid bonding process such as a hybrid copper bonding (HCB) process, a large number of components may be integrated in an IC device with a limited device area. It will also be appreciated that, by stacking two wafers vertically and using a hybrid bonding process, an integrated power via may be provided for the circuits of both wafers. It will be further appreciated that, by stacking two wafers vertically and using a hybrid bonding process to form integrated electrical connections between the bonding pads of the two wafers, the speed and performance of the IC device may be improved.

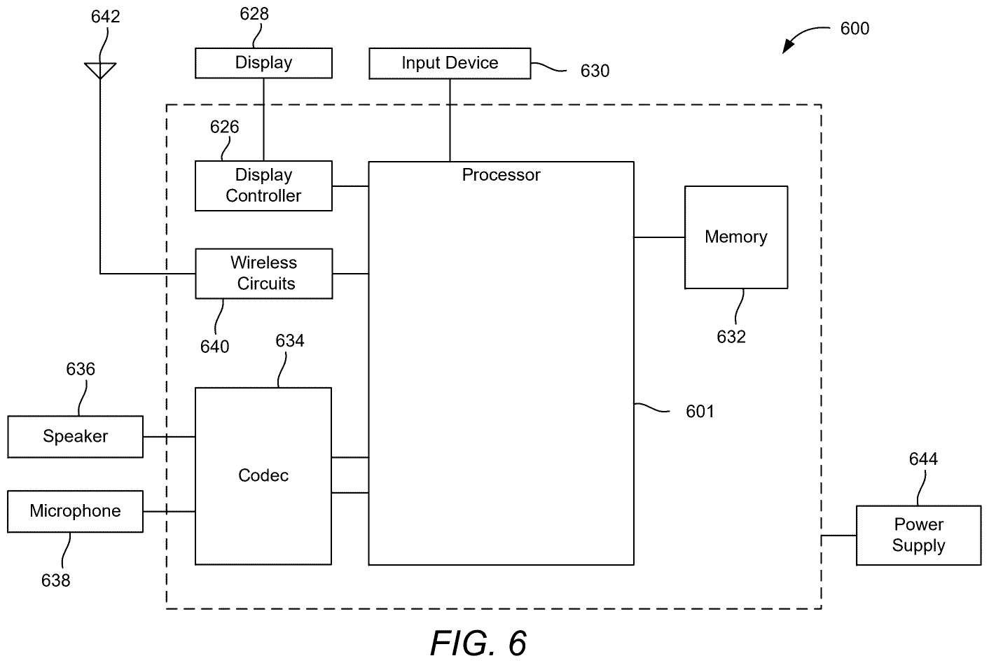

FIG. 6 illustrates a mobile device 600, according to aspects of the disclosure. In some aspects, the mobile device 600 may be implemented by including one or more IC devices including the IC device with a bonded wafer structure as disclosed herein.

In some aspects, mobile device 600 may be configured as a wireless communication device. As shown, mobile device 600 includes processor 601. Processor 601 may be communicatively coupled to memory 632 over a link, which may be a die-to-die or chip-to-chip link. Mobile device 600 also includes display 628 and display controller 626, with display controller 626 coupled to processor 601 and to display 628. The mobile device 600 may include input device 630 (e.g., physical, or virtual keyboard), power supply 644 (e.g., battery), speaker 636, microphone 638, and wireless antenna 642. In some aspects, the power supply 644 may directly or indirectly provide the supply voltage for operating some or all of the components of the mobile device 600.

In some aspects, FIG. 6 may include coder/decoder (CODEC) 634 (e.g., an audio and/or voice CODEC) coupled to processor 601; speaker 636 and microphone 638 coupled to CODEC 634; and wireless circuits 640 (which may include a modem, RF circuitry, filters, etc.) coupled to wireless antenna 642 and to processor 601.

In some aspects, one or more of processor 601 (e.g., SoCs, application processor (AP), central processing unit (CPU), digital signal processor (DSP), etc.), display controller 626, memory 632, CODEC 634, and wireless circuits 640 (e.g., baseband interface) may include one or more IC devices (e.g., IC device 300 as shown in FIG. 3) with a bonded wafer structure according to the various aspects described in this disclosure.

It should be noted that although FIG. 6 depicts a mobile device 600, similar architecture may be used to implement an apparatus including, a microprocessor, a server, a set top box, a music player, a video player, an entertainment unit, a navigation device, a personal digital assistant (PDA), a fixed location data unit, a computer, a laptop, a tablet, a communications device, a mobile phone, or other similar devices. In some implementations, structures described herein according to aspects of the disclosure may be used for expanding the L3 cache by adding a static random access memory (SRAM) in a second layer on top of a CPU or GPU, for example.

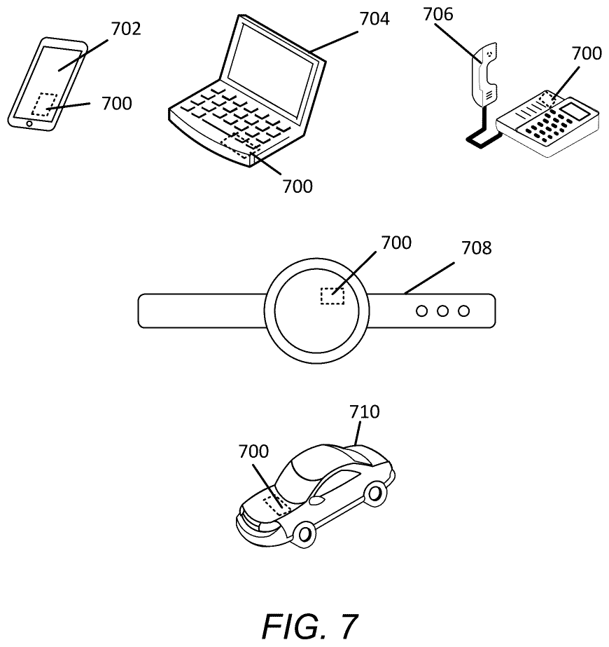

FIG. 7 illustrates various electronic devices that may be integrated with any of the aforementioned devices, semiconductor devices, integrated circuit (IC) packages, integrated circuit (IC) devices, electronic components, interposer packages, package-on-package (POP), System in Package (SiP), or System on Chip (SoC). For example, a mobile phone device 702, a laptop computer device 704, a fixed location terminal device 706, a wearable device 708, or automotive vehicle 710 may include a semiconductor device 700 (e.g., IC device 300 as shown in FIG. 3) as described herein. The devices 702, 704, 706 and 708 and the vehicle 710 illustrated in FIG. 7 are merely exemplary. Other apparatuses or devices may also feature the semiconductor device 700 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

The devices illustrated in FIG. 7 are merely non-limiting examples. Other electronic devices may also feature the semiconductor devices as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-4 may be rearranged and/or combined into a single component, process, feature, or function or incorporated in several components, processes, or functions. Additional elements, components, processes, and/or functions may also be added without departing from the disclosure. In some implementations, FIGS. 1-4 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1: A device, comprising: a first wafer, comprising: a first dielectric layer; a first plurality of bonding pads disposed in the first dielectric layer; and a first circuit disposed on the first dielectric layer; and a second wafer, comprising: a second dielectric layer; a second plurality of bonding pads disposed in the second dielectric layer; and a second circuit disposed on the second dielectric layer; a plurality of through-vias including at least one power via through at least the second dielectric layer in the second wafer; and a backside power distribution network (BSPDN) layer disposed on the second wafer, the BSPDN layer including at least one component electrically connected to the at least one power via, wherein the first plurality of bonding pads is bonded with the second plurality of bonding pads.

Clause 2: The device of clause 1, wherein the first plurality of bonding pads comprise a first plurality of hybrid bonding pads, and the second plurality of bonding pads comprise a second plurality of hybrid bonding pads.

Clause 3: The device of any of clauses 1 to 2, wherein the first plurality of bonding pads is bonded with the second plurality of bonding pads by hybrid copper bonding (HCB).

Clause 4: The device of any of clauses 1 to 3, wherein the first wafer is bonded with the second wafer by wafer-on-wafer (WOW) bonding.

Clause 5: The device of any of clauses 1 to 4, wherein the first circuit comprises: a third dielectric layer; and a first plurality of metal contacts disposed in the third dielectric layer.

Clause 6: The device of any of clauses 1 to 5, wherein the first circuit further comprises a first plurality of transistors disposed on the third dielectric layer.

Clause 7: The device of any of clauses 1 to 6, wherein the second circuit further comprises: a fourth dielectric layer; and a second plurality of metal contacts disposed in the fourth dielectric layer, wherein at least one of the second plurality of metal contacts is connected to the at least one power via.

Clause 8: The device of any of clauses 1 to 7, wherein the second circuit further comprises a second plurality of transistors disposed on the fourth dielectric layer.

Clause 9: The device of any of clauses 1 to 8, further comprising a stop layer disposed between the second wafer and the BSPDN layer.

Clause 10: The device of any of clauses 1 to 9, wherein the BSPDN layer comprises: a dielectric layer; and a plurality of BSPDN metal contacts disposed in the dielectric layer, wherein at least one of the BSPDN metal contacts is connected to the at least one power via.

Clause 11: The device of any of clauses 1 to 10, further comprising a passivation layer disposed on the BSPDN layer.

Clause 12: The device of any of clauses 1 to 11, further comprising a plurality of bumps disposed on the passivation layer.

Clause 13: The device of any of clauses 1 to 12, wherein the first circuit includes a digital circuit, an analog circuit, a mixed signal circuit, a radio frequency (RF) circuit, a power circuit, a memory circuit, a processor circuit, or any combination thereof.

Clause 14: The device of any of clauses 1 to 13, wherein the second circuit includes a digital circuit, an analog circuit, a mixed signal circuit, a radio frequency (RF) circuit, a power circuit, a memory circuit, a processor circuit, or any combination thereof.

Clause 15: A method of manufacturing a device, comprising: forming a first wafer comprising a first dielectric layer, a first plurality of bonding pads disposed in the first dielectric layer, and a first circuit disposed on the first dielectric layer; forming a second wafer comprising a second dielectric layer, a second plurality of bonding pads disposed in the second dielectric layer, and a second circuit disposed on the second dielectric layer; forming a plurality of through-vias including at least one power via in the second wafer; forming a backside power distribution network (BSPDN) layer disposed on the second wafer; and bonding the first plurality of bonding pads with the second plurality of bonding pads.

Clause 16: The method of clause 15, wherein the first plurality of bonding pads comprise a first plurality of hybrid bonding pads, and the second plurality of bonding pads comprise a second plurality of hybrid bonding pads.

Clause 17: The method of any of clauses 15 to 16, wherein bonding the first plurality of bonding pads with the second plurality of bonding pads comprises hybrid copper bonding the first plurality of bonding pads with the second plurality of bonding pads.

Clause 18: The method of any of clauses 15 to 17, wherein bonding the first plurality of bonding pads with the second plurality of bonding pads comprises wafer-on-wafer bonding the first plurality of bonding pads with the second plurality of bonding pads.

Clause 19: An apparatus, comprising: a device that comprises: a first wafer, comprising: a first dielectric layer; a first plurality of bonding pads disposed in the first dielectric layer; and a first circuit disposed on the first dielectric layer; and a second wafer, comprising: a second dielectric layer; a second plurality of bonding pads disposed in the second dielectric layer; and a second circuit disposed on the second dielectric layer; a plurality of through-vias including at least one power via in the second wafer; and a backside power distribution network (BSPDN) layer disposed on the second wafer, wherein the first plurality of bonding pads is bonded with the second plurality of bonding pads.

Clause 20: The apparatus of clause 19, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such. Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

What is claimed is:

1. A device, comprising:
a first wafer, comprising:
a first dielectric layer;
a first plurality of bonding pads disposed in the first dielectric layer; and
a first circuit disposed on the first dielectric layer; and
a second wafer, comprising:
a second dielectric layer;
a second plurality of bonding pads disposed in the second dielectric layer; and
a second circuit disposed on the second dielectric layer;
a plurality of through-vias including at least one power via through at least the second dielectric layer in the second wafer; and
a backside power distribution network (BSPDN) layer disposed on the second wafer, the BSPDN layer including at least one component electrically connected to the at least one power via,
wherein the first plurality of bonding pads is bonded with the second plurality of bonding pads.

2. The device of claim 1, wherein the first plurality of bonding pads comprise a first plurality of hybrid bonding pads, and the second plurality of bonding pads comprise a second plurality of hybrid bonding pads.

3. The device of claim 1, wherein the first plurality of bonding pads is bonded with the second plurality of bonding pads by hybrid copper bonding (HCB).

4. The device of claim 1, wherein the first wafer is bonded with the second wafer by wafer-on-wafer (WOW) bonding.

5. The device of claim 1, wherein the first circuit comprises:
a third dielectric layer; and
a first plurality of metal contacts disposed in the third dielectric layer.

6. The device of claim 5, wherein the first circuit further comprises a first plurality of transistors disposed on the third dielectric layer.

7. The device of claim 1, wherein the second circuit further comprises:
a fourth dielectric layer; and
a second plurality of metal contacts disposed in the fourth dielectric layer, wherein at least one of the second plurality of metal contacts is connected to the at least one power via.

8. The device of claim 7, wherein the second circuit further comprises a second plurality of transistors disposed on the fourth dielectric layer.

9. The device of claim 1, further comprising a stop layer disposed between the second wafer and the BSPDN layer.

10. The device of claim 1, wherein the BSPDN layer comprises:
a dielectric layer; and
a plurality of BSPDN metal contacts disposed in the dielectric layer, wherein at least one of the BSPDN metal contacts is connected to the at least one power via.

11. The device of claim 1, further comprising a passivation layer disposed on the BSPDN layer.

12. The device of claim 11, further comprising a plurality of bumps disposed on the passivation layer.

13. The device of claim 1, wherein the first circuit includes a digital circuit, an analog circuit, a mixed signal circuit, a radio frequency (RF) circuit, a power circuit, a memory circuit, a processor circuit, or any combination thereof.

14. The device of claim 1, wherein the second circuit includes a digital circuit, an analog circuit, a mixed signal circuit, a radio frequency (RF) circuit, a power circuit, a memory circuit, a processor circuit, or any combination thereof.

15. A method of manufacturing a device, comprising:
forming a first wafer comprising a first dielectric layer, a first plurality of bonding pads disposed in the first dielectric layer, and a first circuit disposed on the first dielectric layer;
forming a second wafer comprising a second dielectric layer, a second plurality of bonding pads disposed in the second dielectric layer, and a second circuit disposed on the second dielectric layer;
forming a plurality of through-vias including at least one power via in the second wafer;
forming a backside power distribution network (BSPDN) layer disposed on the second wafer; and
bonding the first plurality of bonding pads with the second plurality of bonding pads.

16. The method of claim 15, wherein the first plurality of bonding pads comprise a first plurality of hybrid bonding pads, and the second plurality of bonding pads comprise a second plurality of hybrid bonding pads.

17. The method of claim 15, wherein bonding the first plurality of bonding pads with the second plurality of bonding pads comprises hybrid copper bonding the first plurality of bonding pads with the second plurality of bonding pads.

18. The method of claim 15, wherein bonding the first plurality of bonding pads with the second plurality of bonding pads comprises wafer-on-wafer bonding the first plurality of bonding pads with the second plurality of bonding pads.

19. An apparatus, comprising:
a device that comprises:
a first wafer, comprising:
a first dielectric layer;
a first plurality of bonding pads disposed in the first dielectric layer; and
a first circuit disposed on the first dielectric layer; and
a second wafer, comprising:
a second dielectric layer;
a second plurality of bonding pads disposed in the second dielectric layer; and
a second circuit disposed on the second dielectric layer;
a plurality of through-vias including at least one power via in the second wafer; and
a backside power distribution network (BSPDN) layer disposed on the second wafer,
wherein the first plurality of bonding pads is bonded with the second plurality of bonding pads.

20. The apparatus of claim 19, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
